(19) United States
(12) Patent Application Publication
(10) Pub. No.: US 2026/0065993 A1
(43) Pub. Date: Mar. 5, 2026

(54) INPUT BUFFER IN MEMORY DEVICES AND MEMORY SYSTEMS

(71) Applicant: Yangtze Memory Technologies Co., Ltd., Wuhan (CN)

(72) Inventors: Tao YANG, Wuhan (CN); Byoungwoon LEE, Wuhan (CN); Shu XIE, Wuhan (CN); Jiawei CHEN, Wuhan (CN)

(21) Appl. No.: 18/896,748

(22) Filed: Sep. 25, 2024

Related U.S. Application Data
(63) Continuation of application No. PCT/CN2024/115703, filed on Aug. 30, 2024.

(51) Int. Cl. G11C 16/06; G11C 16/04; H03F 3/45; H03K 3/037

(52) U.S. Cl. CPC G11C 16/06; G11C 16/0483; H03F 3/45179; H03K 3/037; H03F 2203/45022

(57) ABSTRACT

Input buffers of memory devices, memory devices, and memory systems are provided. In one aspect, an input buffer of a memory device includes a first circuit and a second circuit coupled to the first circuit. The first circuit is configured to receive an input voltage and a reference voltage, and generate differential voltages based on the input voltage and the reference voltage. The second circuit is configured to receive the differential voltages from the first circuit, and generate an amplified voltage of the input voltage based on the differential voltages. The second circuit includes an active inductor.

### CROSS-REFERENCE TO RELATED APPLICATIONS

This application is a continuation of International Application No. PCT/CN2024/115703, filed on Aug. 30, 2024, the disclosure of which is hereby incorporated by reference in its entirety.

### TECHNICAL FIELD

The present disclosure relates to semiconductor devices, e.g., memory devices.

### BACKGROUND

In a non-volatile memory device, such as a NAND Flash memory, or a NOR Flash memory, data stored in the memory device are preserved when power is turned off. In contrast, in a volatile memory device, such as a Dynamic Random Access Memory (DRAM) or a Static Random Access Memory (SRAM), data stored in the memory device are lost when power is turned off.

### SUMMARY

The present disclosure provides an input buffer of a memory device, a memory device, and a memory system.

One aspect of the present disclosure features an input buffer of a memory device. The input buffer includes a first circuit and a second circuit coupled to the first circuit. The first circuit is configured to receive an input voltage and a reference voltage, and generate differential voltages based on the input voltage and the reference voltage. The second circuit is configured to receive the differential voltages from the first circuit, and generate an amplified voltage of the input voltage based on the differential voltages. The second circuit includes an active inductor.

In some implementations, the active inductor includes a CMOS transmission gate and a first inverter coupled in parallel.

In some implementations, the first circuit includes a first current-mode logic (CML) and a second CML circuit. The first CML circuit includes a first transistor that receives the input voltage and outputs a first differential voltage, and a second transistor that receives the reference voltage and outputs a second differential voltage. The second CML circuit includes a third transistor that receives the first differential voltage and outputs a third differential voltage, and a fourth transistor that receives the second differential voltage and outputs a fourth differential voltage.

In some implementations, the second CML circuit includes a negative capacitor.

In some implementations, the negative capacitor includes a fifth transistor coupled between an input of the third transistor and an output of the fourth transistor, and a sixth transistor coupled between an input of the fourth transistor and an output of the third transistor.

In some implementations, the second circuit includes an operational transconductance-amplifier (OTA) circuit that includes a seventh transistor that receives the third differential voltage and an eighth transistor that receives the fourth differential voltage. The active inductor is coupled to an output of the OTA circuit.

In some implementations, the active inductor is coupled to one or more second inverters that are coupled in series. The one or more second inverters output the amplified voltage.

In some implementations, the first circuit and the second circuit are placed on a printed circuit board (PCB). At least a portion of the active inductor is placed between the OTA circuit and the one or more second inverters.

In some implementations, a CMOS transmission gate and a first inverter of the active inductor are placed on the PCB, between transistors included in the OTA circuit, and transistors included in the one or more second inverters.

In some implementations, a channel of a transistor included in a CMOS transmission gate of the active inductor is arranged along a first direction, and channels of the transistors included in the one or more second inverters are arranged in a second direction. The first direction is perpendicular to the second direction.

In some implementations, a first inverter of the active inductor is placed between transistors included in the OTA circuit and transistors included in the one or more second inverters along a third direction. A CMOS transmission gate of the active inductor is offset from the third direction.

In some implementations, a channel of a transistor included in a CMOS transmission gate of the active inductor is arranged along a first direction. Channels of the transistors included in the one or more second inverters are arranged in a second direction. The first direction is parallel to the second direction.

One aspect of the present disclosure features a memory device. The memory device includes an input/output interface that includes an input buffer. The input buffer includes a first circuit and a second circuit coupled to the first circuit. The first circuit is configured to receive an input voltage and a reference voltage, and generate differential voltages based on the input voltage and the reference voltage. The second circuit is configured to receive the differential voltages from the first circuit, and generate an amplified voltage of the input voltage based on the differential voltages. The second circuit includes an active inductor.

One aspect of the present disclosure features a memory system. The memory system includes a memory device and a memory controller coupled to the memory device and configured to control the memory device. The memory device includes an input/output interface that includes an input buffer. The input buffer includes a first circuit and a second circuit coupled to the first circuit. The first circuit is configured to receive an input voltage and a reference voltage, and generate differential voltages based on the input voltage and the reference voltage. The second circuit is configured to receive the differential voltages from the first circuit, and generate an amplified voltage of the input voltage based on the differential voltages. The second circuit includes an active inductor.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a block diagram of an example system having one or more semiconductor devices, according to some aspects of the present disclosure.

FIG. 2 illustrates an example of a schematic diagram of a memory device including peripheral circuits, according to some aspects of the present disclosure.

FIG. 3 illustrates some example peripheral circuits, according to some aspects of the present disclosure.

FIG. 4 illustrates a schematic diagram of an example memory device including a peripheral circuit and an array of memory cells each having a vertical transistor, according to some aspects of the present disclosure.

FIG. 5 illustrates memory device having a memory array and an example peripheral circuit, according to some aspects of the present disclosure.

FIG. 6A illustrates a schematic view of a cross-section of a memory device, according to some aspects of the present disclosure.

FIG. 6B illustrates a schematic view of a cross-section of a memory device, according to some aspects of the present disclosure.

FIG. 7 illustrates a schematic block diagram of an input/output (I/O) interface, according to some aspects of the present disclosure.

FIG. 8 illustrates an example input buffer of an I/O interface of a memory device, according to some aspects of the present disclosure.

FIGS. 9A-9C illustrate schematic circuit diagrams of components of an example input buffer, according to some aspects of the present disclosure.

FIG. 10A illustrates an example frequency response curve of an active inductor, according to some aspects of the present disclosure.

FIG. 10B illustrates example frequency response curves of an operational transconductance-amplifier (OTA) circuit, according to some aspects of the present disclosure.

FIG. 11 illustrates an example floor plan of an I/O interface including a plurality of input buffers, according to some aspects of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

This specification relates to input buffers, and memory devices and memory systems having the input buffers. As the data rate of an input/output (I/O) interface of a memory device (e.g., a NAND memory device or a DRAM memory device) increases, data rate and overall performance of input buffers in the I/O interface also needs improvement.

The present disclosure provides techniques to improve the performance of input buffers of a memory device. An input buffer can include a first current mode logic (CML) circuit configured to generate differential voltages based on an input voltage, a second CML circuit configured to amplify the differential voltages, and an operational transconductance-amplifier (OTA) circuit configured to generate a singled-ended output voltage based on the amplified differential voltages. The singled-ended output voltage amplifies the input voltage. In some implementations, the second CML circuit can include a negative capacitor to offset parasitic capacitance of the first CML circuit, thereby expanding the bandwidth and increasing the speed of the first CML circuit. In some implementations, the OTA circuit is coupled to an active inductor, which can expand the bandwidth and increase the speed of the OTA circuit.

Implementations of the present disclosure can provide one or more of the following technical advantages. For example, by including the negative capacitor in the second CML circuit, the performance of the first CML circuit can be improved without increasing the current in the first CML circuit. As such, when the input buffer is operating in a low-speed mode, current in the first CML circuit does not exceed a safety threshold, so that transistors in the first CML circuit can work within a safe operating area (SOA). For another example, by including the active inductor, the performance of the OTA circuit can be improved without introducing passive inductors, significantly increasing a circuit area, or substantially increasing the power consumption of the input buffer. In addition, the overall data rate and the performance of the input buffer and the I/O interface can be improved. In some implementations, additional or different technical advantages may be achieved.

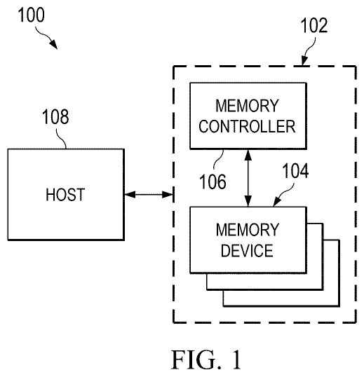

FIG. 1 illustrates a block diagram of an example system 100 having one or more semiconductor devices (e.g., memory devices), according to some aspects of the present disclosure. The system 100 can be a mobile phone, a desktop computer, a laptop computer, a tablet, a server, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include a host 108 and a memory system 102 having one or more memory devices 104 and a memory controller 106. Host 108 can include a processor of an electronic device, such as a central processing unit (CPU), or a system-on-chip (SoC), such as an application processor (AP). Host 108 can be configured to send or receive data to or from the one or more memory devices 104.

A memory device 104 can be any memory device disclosed herein. In some implementations, the memory device 104 includes a DRAM memory. Memory controller 106 (a.k.a., a controller circuit) is coupled to memory device 104 and host 108. Consistent with implementations of the present disclosure, memory device 104 can include a plurality of conductive interconnections through a cover layer that are in contact with conductive pads in a conductive pad layer, and memory controller 106 can be coupled to memory device 104 through at least one of the plurality of conductive interconnections. Memory controller 106 is configured to control memory device 104. Memory controller 106 can manage data stored in memory device 104 and communicate with host 108.

In some implementations, memory controller 106 can be configured to control operations of memory device 104, such as read, program (or write) operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, formatting memory device 104.

Memory controller 106 can communicate with an external device (e.g., host 108) according to a particular communication protocol. For example, memory controller 106 may communicate with the external device through at least one of various interface protocols, such as a USB protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

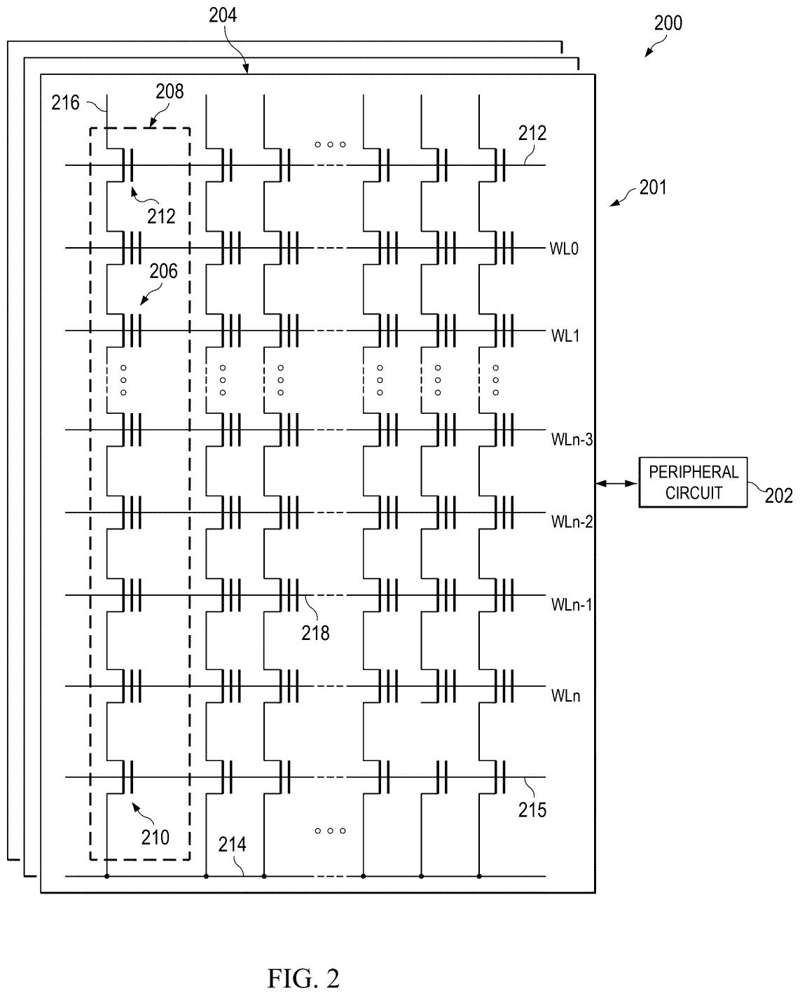

FIG. 2 illustrates an example of a schematic diagram of a memory device 200 including peripheral circuits, according to some aspects of the present disclosure. The memory device 200 can include a memory array 201 and peripheral circuits 202 coupled to the memory array 201. The memory array 201 can be a NAND Flash memory array in which memory cells 206 are provided in the form of an array of NAND memory strings 208 each extending vertically above a substrate (not shown in FIG. 2). In some implementations, each NAND memory string 208 includes a plurality of memory cells 206 coupled in series and stacked vertically. Each memory cell 206 can hold a continuous, analog value, such as an electrical voltage or charge that depends on the number of electrons trapped within a storage layer of the memory cell 206. The logic state (i.e., data) of each memory cell 206 in a memory block 204 can be determined based on the threshold voltage Vth of the memory cell 206. Each memory cell 206 can be a floating gate type memory cell including a floating-gate transistor, or a charge trap type memory cell including a charge-trap transistor.

In some implementations, each memory cell 206 is a single-level cell (SLC) with two possible memory states that can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 2, each NAND memory string 208 can include a source select gate (SSG) 210 at its source end and a drain select gate (DSG) 212 at its drain end. The SSG 210 and the DSG 212 can be configured to activate selected NAND memory strings 208 (columns of the array) during read and program operations. In some implementations, the sources of NAND memory strings 208 in the same memory block 204 are coupled through a same source line (SL) 214, e.g., a common SL. In other words, NAND memory strings 208 in the same memory block 204 have an array common source (ACS), according to some implementations. The DSG 212 of each NAND memory string 208 is coupled to a respective bit line 216 from which data can be read or written via an output bus (not shown), according to some implementations. In some implementations, each NAND memory string 208 is configured to be selected or deselected by applying a select voltage (e.g., above the threshold voltage of the transistor having the DSG 212) or a deselect voltage (e.g., 0 V) to the respective DSG 212 through one or more DSG lines 213, and/or by applying a select voltage (e.g., above the threshold voltage of the transistor having the SSG 210) or a deselect voltage (e.g., 0 V) to the respective SSG 210 through one or more SSG lines 215.

As shown in FIG. 2, NAND memory strings 208 can be organized into multiple memory blocks 204, each of which can have a common SL 214 coupled to the ACS. In some implementations, each memory block 204 can serve as a basic data unit for erase operations, such that memory cells 206 on the same memory block 204 are erased at the same time. To erase memory cells 206 in a selected memory block 204, the SL 214 coupled to the selected memory block 204 and unselected memory blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of memory blocks or fractions of a memory block.

The memory cells 206 of adjacent NAND memory strings 208 can be coupled through word lines 218. The word line 218 can select which row of memory cells 206 is affected by read and program operations. Each word line 218 can include a gate line coupled to a plurality of control gates (gate electrodes) of a plurality of memory cells 206. Example word lines shown in FIG. 2 include WL0, WL1, WLn−3, WLn−2, WLn−1, and WLn that are between one or more DSG lines 213 and one or more SSG lines 215.

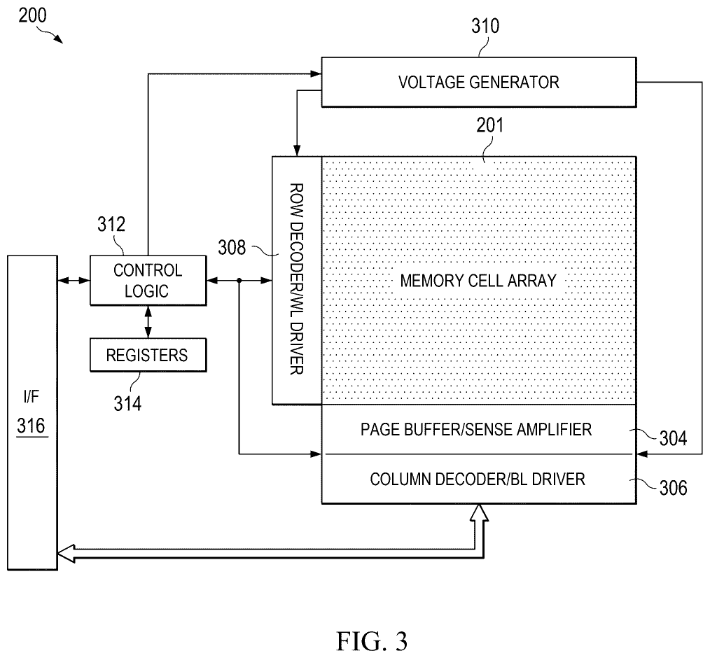

FIG. 3 illustrates some example peripheral circuits 202, according to some aspects of the present disclosure. The peripheral circuits 202 can be coupled to the memory array 201 through bit lines 216, word lines 218, SLs 214, SSG lines 215, and DSG lines 213. The peripheral circuits 202 can include any suitable analog, digital, and mixed-signal circuits for facilitating the operations of the memory array 201 by applying and sensing voltage signals and/or current signals to and from each target memory cell 206 through bit lines 216, word lines 218, SLs 214, SSG lines 215, and DSG lines 213. The peripheral circuits 202 can include various types of peripheral circuits formed using metal-oxide-semiconductor (MOS) technologies. The example peripheral circuits 202 include a page buffer/sense amplifier 304, a column decoder/bit line driver 306, a row decoder/word line driver 308, a voltage generator 310, control logic 312, registers 314, an input/output (I/O) interface 316, and a data bus. In some examples, additional peripheral circuits not shown in FIG. 3 may be included as well.

The page buffer/sense amplifier 304 can be configured to read and program (write) data from and to memory array 201 according to the control signals from control logic 312. In an example, the page buffer/sense amplifier 304 may store one page of program data (write data) to be programmed into one page of the memory array 201. In another example, the page buffer/sense amplifier 304 may perform program verify operations to ensure that the data have been properly programmed into memory cells 206 coupled to selected word lines 318. In still another example, the page buffer/sense amplifier 304 may also sense the low power signals from the bit line 216 that represents a data bit stored in memory cell 206, and amplify the small voltage swing to recognizable logic levels in a read operation. The column decoder/bit line driver 306 can be configured to be controlled by the control logic 312 and select one or more NAND memory strings 208 by applying bit line voltages generated from the voltage generator 310.

The row decoder/word line driver 308 can be configured to be controlled by the control logic 312 and select/deselect memory blocks 204 of the memory array 201 and select/deselect word lines 318 of the memory block 204. The row decoder/word line driver 308 can be further configured to drive word lines 318 using word line voltages generated from the voltage generator 310. In some implementations, the row decoder/word line driver 308 can also select/deselect and drive SSG lines 215 and DSG lines 213. As described below in detail, the row decoder/word line driver 308 is configured to apply a program voltage to selected word line 318 in a program operation on memory cell 206 coupled to selected word line 318.

The voltage generator 310 can be configured to be controlled by the control logic 312 and generate the word line voltages (e.g., read voltage, program voltage, pass voltage, local voltage, verify voltage, etc.), bit line voltages, and source line voltages to be supplied to the memory array 201.

The control logic 312 can be coupled to each peripheral circuit described above and configured to control operations of each peripheral circuit. The registers 314 can be coupled to the control logic 312 and include status registers, command registers, and address registers for storing status information, command operation codes (OP codes), and command addresses for controlling the operations of each peripheral circuit.

The I/O interface 316 can be coupled to the control logic 312 and act as a control buffer to buffer and relay control commands received from a host (not shown) to the control logic 312 and status information received from the control logic 312 to the host. The I/O interface 316 can also be coupled to the column decoder/bit line driver 306 via a data bus, and act as a data input/output interface and a data buffer to buffer and relay data to and from the memory array 201.

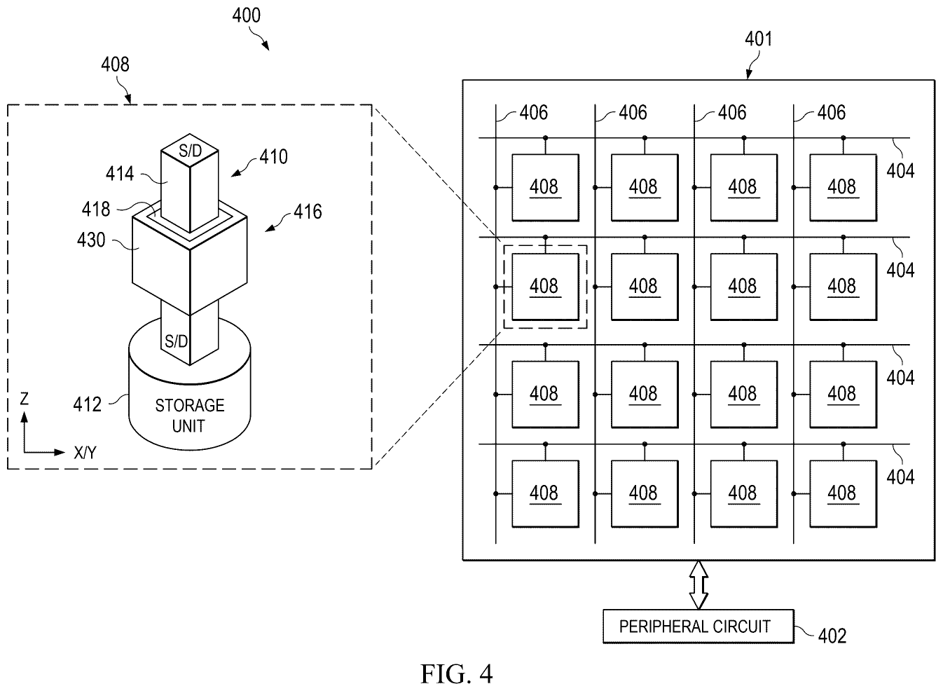

FIG. 4 illustrates a schematic diagram of a memory device 400 including peripheral circuits and an array of memory cells each having a vertical transistor, according to some aspects of the present disclosure. Memory device 400 can include a memory array 401 and peripheral circuits 402 coupled to memory array 401. Memory array 401 can be any suitable memory array in which each memory cell 408 includes a vertical transistor 410 and a storage unit 412 coupled to vertical transistor 410. In some implementations, memory array 401 is a DRAM cell array, and storage unit 412 is a capacitor for storing charge as the binary information stored by the respective DRAM cell. In some implementations, memory array 401 is a PCM cell array, and storage unit 412 is a PCM element (e.g., including chalcogenide alloys) for storing binary information of the respective PCM cell based on the different resistivities of the PCM element in the amorphous phase and the crystalline phase. In some implementations, memory array 401 is a FRAM cell array, and storage unit 412 is a ferroelectric capacitor for storing binary information of the respective FRAM cell based on the switch between two polarization states of ferroelectric materials under an external electric field.

As shown in FIG. 4, memory cells 408 can be arranged in a two-dimensional (2D) array having rows and columns. Memory device 400 can include word lines 404 coupling peripheral circuits 402 and memory array 401 for controlling the switch of vertical transistors 410 in memory cells 408 located in a row, as well as bit lines 406 coupling peripheral circuits 402 and memory array 401 for sending data to and/or receiving data from memory cells 408 located in a column. That is, each word line 404 is coupled to a respective row of memory cells 408, and each bit line is coupled to a respective column of memory cells 408.

Consistent with the scope of the present disclosure, vertical transistors 410, such as vertical metal-oxide-semiconductor field-effect transistors (MOSFETs), can replace the planar transistors as the pass transistors of memory cells 408 to reduce the area occupied by the pass transistors, the coupling capacitance, as well as the interconnect routing complexity, as described below in detail. As shown in FIG. 4, in some implementations, different from planar transistors in which the active regions are formed in the substrates, vertical transistor 410 includes a semiconductor body 414 extending vertically (in the Z-direction) above the substrate (not shown). That is, semiconductor body 414 can extend above the top surface of the substrate to allow channels to be formed not only at the top surface of semiconductor body 414, but also at one or more side surfaces thereof. As shown in FIG. 4, for example, semiconductor body 414 can have a cuboid shape to expose four sides thereof. It is understood that semiconductor body 414 may have any suitable 3D shape, such as polyhedron shapes or a cylinder shape. That is, the cross-section of semiconductor body 414 in the plan view (e.g., in the X-Y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered as having multiple sides, such that the gate structures is in contact with more than one side of the semiconductor bodies. As described below with respect to the fabrication process, semiconductor body 414 can be formed from the substrate (e.g., by etching or epitaxy) and thus, has the same semiconductor material (e.g., silicon crystalline silicon) as the substrate (e.g., a silicon substrate).

As shown in FIG. 4, vertical transistor 410 can also include a gate structure 416 in contact with one or more sides of semiconductor body 414, e.g., in one or more planes of the side surface(s) of the active region. In other words, the active region of vertical transistor 410, e.g., semiconductor body 414, can be at least partially surrounded by gate structure 416. Gate structure 416 can include a gate dielectric 418 over one or more sides of semiconductor body 414, e.g., in contact with four side surfaces of semiconductor body 414, as shown in FIG. 4. Gate structure 416 can also include a gate electrode 420 over and in contact with gate dielectric 418. Gate dielectric 418 can include any suitable dielectric materials, such as silicon oxide, silicon nitride, silicon oxynitride, or high-k dielectrics. For example, gate dielectric 418 may include silicon oxide, which is a form of gate oxide. Gate electrode 420 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 420 may include doped polysilicon, which is a form of a gate poly. In some implementations, gate electrode 420 includes multiple conductive layers, such as a W layer over a TiN layer. It is understood that gate electrode 420 and word line 404 may be a continuous conductive structure in some examples. In other words, gate electrode 420 may be viewed as part of word line 404 that forms gate structure 416, or word line 404 may be viewed as the extension of gate electrode 420 to be coupled to peripheral circuits 402.

As shown in FIG. 4, vertical transistor 410 can further include a pair of a source and a drain (S/D, dope regions, a.k.a., source electrode and drain electrode) formed at the two ends of semiconductor body 414 in the vertical direction (the Z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 416 in the vertical direction (the Z-direction). In other words, gate structure 416 is formed vertically between the source and drain. As a result, one or more channels (not shown) of vertical transistor 410 can be formed in semiconductor body 414 vertically between the source and drain when a gate voltage applied to gate electrode 420 of gate structure 416 is above the threshold voltage of vertical transistor 410. That is, each channel of vertical transistors 410 is also formed in the vertical direction along which semiconductor body 414 extends, according to some implementations.

In some implementations, as shown in FIG. 4, vertical transistor 410 is a multi-gate transistor. That is, gate structure 416 can be in contact with more than one side of semiconductor body 414 (e.g., four sides in FIG. 4) to form more than one gate, such that more than one channel can be formed between the source and drain in operation. That is, different from the planar transistor that includes only a single planar gate (and resulting in a single planar channel), vertical transistor 410 shown in FIG. 4 can include multiple vertical gates on multiple sides of semiconductor body 414 due to the 3D structure of semiconductor body 414 and gate structure 416 that surrounds the multiple sides of semiconductor body 414. As a result, compared with planar transistors, vertical transistor 410 shown in FIG. 4, can have a larger gate control area to achieve better channel control with a smaller subthreshold swing. Since the channel is fully depleted, the leakage current (Ioff) of vertical transistor 410 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 410 is shown as a multi-gate transistor in FIG. 4, the vertical transistors disclosed herein may also include single-gate transistors as described below in detail. That is, gate structure 416 may be in contact with a single side of semiconductor body 414, for example, for the purpose of increasing the transistor and memory cell density. It is also understood that although gate dielectric 418 is shown as being separate (a separate structure) from other gate dielectrics of adjacent vertical transistors (not shown), gate dielectric 418 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the X-Y plane), and the source and the drain are disposed at different locations in the same lateral plane (the X-Y plane). In contrast, in vertical transistor 410, semiconductor body 414 extends vertically (in the Z-direction), and the source and the drain are disposed in the different lateral planes, according to some implementations. In some implementations, the source and the drain are formed at two ends of semiconductor body 414 in the vertical direction (the Z-direction), respectively, thereby being overlapped in the plan view. As a result, the area (in the X-Y plane) occupied by vertical transistor 410 can be reduced compared with planar transistors and lateral multiple-gate transistors. Also, the metal wiring coupled to vertical transistors 410 can be simplified as well since the interconnects can be routed in different planes. For example, bit lines 406 and storage units 412 may be formed on opposite sides of vertical transistor 410. In one example, bit line 406 may be coupled to the source or the drain at the upper end of semiconductor body 414, while storage unit 412 may be coupled to the other source or the drain at the lower end of semiconductor body 414.

As shown in FIG. 4, storage unit 412 can be coupled to the source or the drain of vertical transistor 410. Storage unit 412 can include any devices that are capable of storing binary data (e.g., 0 and 1), including but not limited to, capacitors for DRAM cells and FRAM cells, and PCM elements for PCM cells. In some implementations, vertical transistor 410 controls the selection and/or the state switch of the respective storage unit 412 coupled to vertical transistor 410.

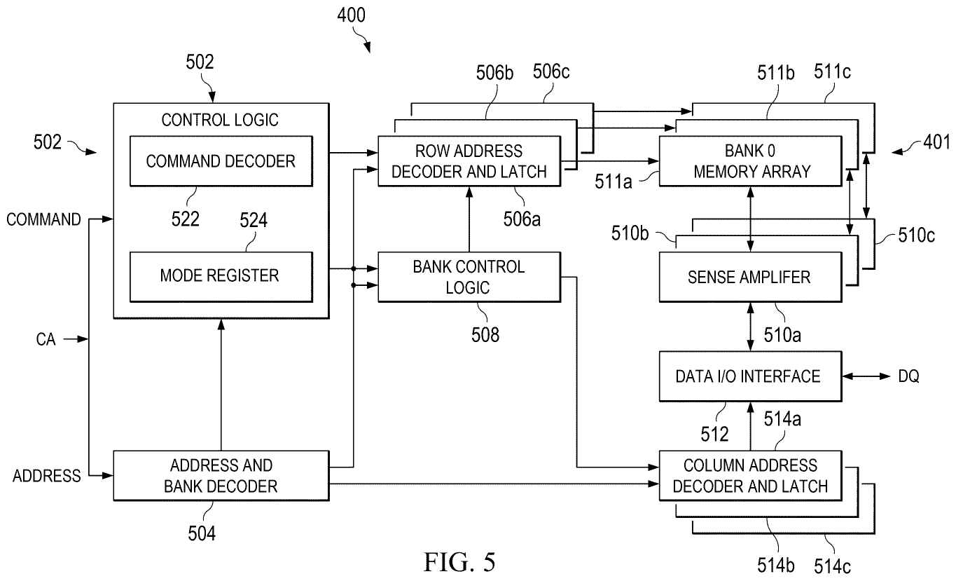

FIG. 5 illustrates memory device having a memory array 401 and an example peripheral circuit 402, according to some aspects of the present disclosure. The peripheral circuit 402 can be coupled to the memory array 401 through bit lines 406 and word lines 404. The peripheral circuit 402 can include any suitable analog, digital, and mixed-signal circuits for facilitating the operations of the memory array 401. The peripheral circuit2 402 can include various types of peripheral circuits formed using metal-oxide-semiconductor (MOS) technologies. The example peripheral circuit 402 include control logic 502, an address and bank decoder 504, a row address decoder and latch 506, bank control logic 508, a sense amplifier 510, a data input/output (I/O) interface 512, and a column address decoder and latch 514. In some examples, additional peripheral circuits not shown in FIG. 5 may be included as well.

In some implementations, the memory array 401 can include a number of memory banks 511. Each memory bank 511 can include memory cells 408 arranged in rows and in columns. Memory banks 511 can be accessed and operated independently from one another. As an example in FIG. 5, the memory array 401 includes three memory banks 511a, 511b, 511c. In other examples, the memory array 401 can include other numbers of memory banks. In some implementations, each memory bank 511a, 511b, 511c can be controlled by a corresponding row address decoder and latch 508a, 508b, 508c, a corresponding sense amplifier 510a, 510b, 510c, and a corresponding column address decoder and latch 514a, 514b, 514c.

In some implementations, the memory banks can be arranged into bank groups, for example, to facilitate parallel operation of accessing memory banks 511 in different bank groups at the same time. For example, each bank group can include N memory banks 511, and the n^{th} memory bank in different bank groups can be accessed at the same time (e.g., during a read or a write operation).

The control logic 502 can be configured to control operations of other circuits in the peripheral circuit 402. The control logic 502 can include a command decoder 522 configured to decode commands received by the memory device 400 (e.g., from the memory controller 106), and generate instructions to be sent to other circuits such as bank control logic 508 and the row address decoder and latch 506. The control logic can also include a number of registers, such as mode registers 524 that store information such as configuration parameters, circuit status, pre-set data pattern, etc. Different mode registers 524, or different sets of mode registers 524, may be designated for different uses.

The address and bank decoder 504 can be configured to decode address signals received from the memory controller. The address and bank decoder 504 can send row addresses, column addresses, and signals indicating selected memory banks decoded from the address signals to the row address decoder and latch 506, the column address decoder and latch 514, and the bank control logic 508, respectively.

The row address decoder and latch 506 can be configured to decode the row address received from the address and bank decoder 504, and enable a word line connected to a memory cell for data to be written to or to be read from, according to the decoded tow address.

The column address decoder and latch 514 can be configured to decode the column address received from the address and bank decoder 504, and enable a bit line connected to a memory cell for data to be written to or to be read from, according to the decoded row address.

The sense amplifier 510 can sense and amplify data of a memory cell and can store data in the memory cell. The sense amplifier 404 can be implemented by a cross-coupled amplifier connected between a bit line and a complementary bit line, which are included in the memory array 401.

The bank control logic 508 can be configured to control operations on selected memory banks 511, for example, by controlling a row address decoder and latch 506a, 506b, 506c, a column address decoder and latch 514a, 514b, 514c, and/or a sense amplifier 510a, 510b, 510c that correspond to a selected memory bank 511a, 511b, 511c.

The data input/output interface 512 can write input data to the memory array 401, and can read output data from the memory array 401. The data input/output interface 512 can include a read latch to temporality hold output data to be read, and a write latch to temporality hold output data to be written. In some implementations, the data input/output interface 512 can include data masking logic configured to select certain portions of data, for example, by masking invalid data bits and keeping valid data bits in a read or a write operation.

The peripheral circuits may further include a clock circuit for generating a clock signal, a power supply circuit generating or distributing internal voltages by receiving power supply voltages applied from outside thereof, or the like.

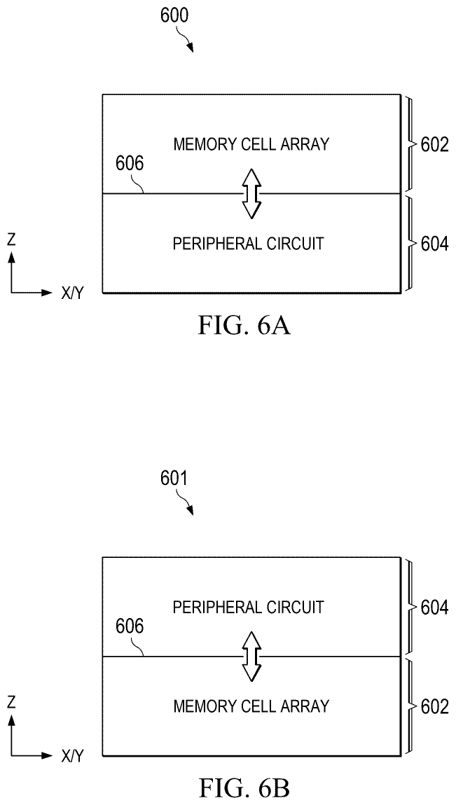

FIG. 6A illustrates a schematic view of a cross-section of a memory device 600 (e.g., the memory device 200 of FIG. 2 or the memory device 400 of FIG. 4), according to some aspects of the present disclosure. The memory device 600 represents an example of a bonded chip. The components of the memory device 600 (e.g., memory array and peripheral circuits) can be formed separately on different substrates and then joined to form a bonded chip. The memory device 600 can include a first semiconductor structure 602 including memory array (e.g., the memory array 201 of FIG. 2, or the memory array 401 of FIG. 4). The memory device 600 can also include a second semiconductor structure 604 including peripheral circuits (e.g., the peripheral circuit 202 of FIG. 2, or the peripheral circuit 402 of FIG. 4). The peripheral circuits in the second semiconductor structure 604 use complementary metal-oxide-semiconductor (CMOS) technology, which can be implemented, for example, with logic processes (e.g., technology nodes of 90 nm, 65 nm, 60 nm, 45 nm, 32 nm, 28 nm, 22 nm, 20 nm, 66 nm, 64 nm, 60 nm, 7 nm, 5 nm, 3 nm, 2 nm, etc.), according to some implementations.

As shown in FIG. 6A, the memory device 600 further includes a bonding interface 606 vertically between (in the vertical direction, e.g., the z-direction in FIG. 6A) the first semiconductor structure 602 and the second semiconductor structure 604. As described below in detail, the first and second semiconductor structures 602 and 604 can be fabricated separately (and in parallel in some implementations) such that the thermal budget of fabricating one of the first and second semiconductor structures 602 and 604 does not limit the processes of fabricating another one of the first and second semiconductor structures 602 and 604. Moreover, a large number of interconnects (e.g., bonding contacts) can be formed through the bonding interface 606 to make direct, short-distance (e.g., micron-level) electrical connections between first semiconductor structure 602 and second semiconductor structure 604, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory array in first semiconductor structure 602 and the peripheral circuits in second semiconductor structure 604 can be performed through the interconnects across the bonding interface 606. By vertically integrating the first and second semiconductor structures 602 and 604, the chip size can be reduced, and the memory cell density can be increased.

It is understood that the relative positions of stacked first and second semiconductor structures 602 and 604 are not limited. FIG. 6B illustrates a schematic view of a cross-section of another memory device 601, according to some aspects of the present disclosure. Different from the memory device 600 in FIG. 6A in which the first semiconductor structure 602 including the memory array is above the second semiconductor structure 604 including the peripheral circuits, in the memory device 601 in FIG. 6B, the second semiconductor structure 604 including the peripheral circuit is above the first semiconductor structure 602 including the memory array. Nevertheless, the bonding interface 606 is formed vertically between the first and second semiconductor structures 602 and 604 in the memory device 601, and the first and second semiconductor structures 602 and 604 are jointed vertically through bonding (e.g., hybrid bonding) according to some implementations. Hybrid bonding, also known as “metal/dielectric hybrid bonding”, is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory array in the first semiconductor structure 602 and the peripheral circuits in the second semiconductor structure 604 can be performed through the interconnects (e.g., bonding contacts) across bonding interface 606.

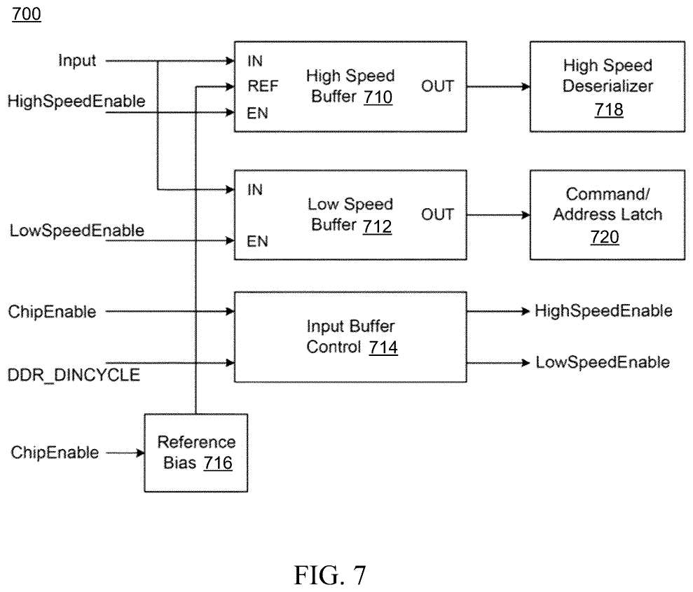

FIG. 7 illustrates a schematic block diagram of an input/output (I/O) interface 700 (e.g., the I/O interface 316 of FIG. 3, or the data I/O interface 512 of FIG. 5), according to some aspects of the present disclosure. The I/O interface 700 can include a high speed buffer 710, a low speed buffer 712, an input buffer control 714, a reference bias 716, a high speed deserializer 718, and a command/address latch 720. The input buffer control 714 can use a ChipEnable signal to select a NAND target, and use a DDR_DINCYCLE signal to detect a command signal, an address signal, or a data signal from input signals. When an input signal is a data signal, the input buffer control 714 can generate a HighSpeedEnable signal and transmit the HighSpeedEnable signal to the high speed buffer 710. The HighSpeedEnable signal enables the high speed buffer 710. When an input signal is a command signal or an address signal, the input buffer control 714 can generate a LowSpeedEnable signal and transmit the LowSpeedEnable signal to the low speed buffer 712. The LowSpeedEnable signal enables the low speed buffer 712. The ChipEnable signal can also enable the reference bias 716 that provides a reference signal to the high speed buffer 710 when the high speed buffer 710 is enabled.

Input signals received by the I/O interface 700 may include a command signal, an address signal, and/or a data signal in the form of differential signals or single-ended signals. The command/address signals are transmitted to the low speed buffer 712. The data signal is transmitted to the high speed buffer 710. Further, the high speed buffer 710 can pass data signals to the high speed deserializer 718 that converts serial data into parallel data. An output of the high speed deserializer 718 can be coupled to a sense amplifier (e.g., the page buffer/sense amplifier 304 of FIG. 3, or the sense amplifier 510 of FIG. 5) of the memory device. The low speed buffer 712 can transfer command/address signals to the command/address latch 720 to store the command or the address, e.g., for further processing by other components of the memory device.

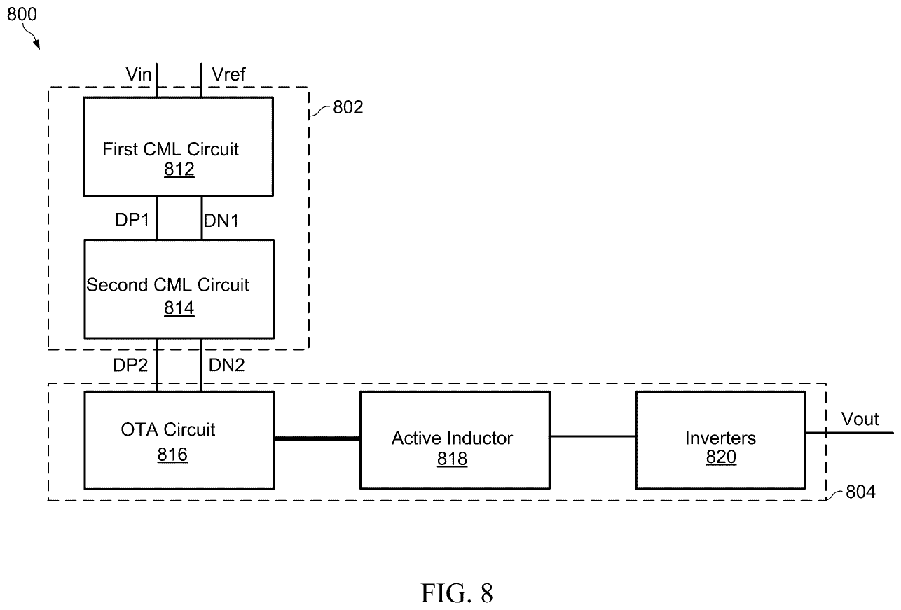

FIG. 8 illustrates an example input buffer 800 of an I/O interface of a memory device, according to some aspects of the present disclosure. The input buffer 800 can be used in the I/O interface of a NAND memory device and or a DRAM memory device. For example, the input buffer 800 can be the high speed buffer 710 of FIG. 7. The input buffer 800 can include a first circuit 802 and a second circuit 804 coupled to the first circuit 802. The first circuit 802 includes a first current mode logic (CML) circuit 812 and a second CML circuit 814. The second circuit 804 includes an operational transconductance-amplifier (OTA) circuit 816, an active inductor 818 and inverters 820.

The first CML circuit 812 can convert an input voltage (Vin) in the form of single-ended voltage into differential voltages (DP1 and DN1). For example, the input voltage can be received from a memory controller (e.g., the memory controller 106 of FIG. 1) coupled to the memory device. The differential voltages DP1 and DN1 can be equal in magnitude but opposite in phase. In some implementations, the magnitude of the differential voltages (DP1, DN1) are greater than the magnitude of the input voltage, so that the input voltage is amplified. The first CML circuit 812 can generate the differential voltages based on the input voltage and a reference voltage (Vref) generated by a reference bias (e.g., reference bias 716 of FIG. 7). The reference voltage can be determined based on the operating mode of the memory device (e.g., under a DDR3, a DDR4, or a DDR4 a/b operating mode). The differential voltages (DP1, DN1) are output to the second CML circuit 814.

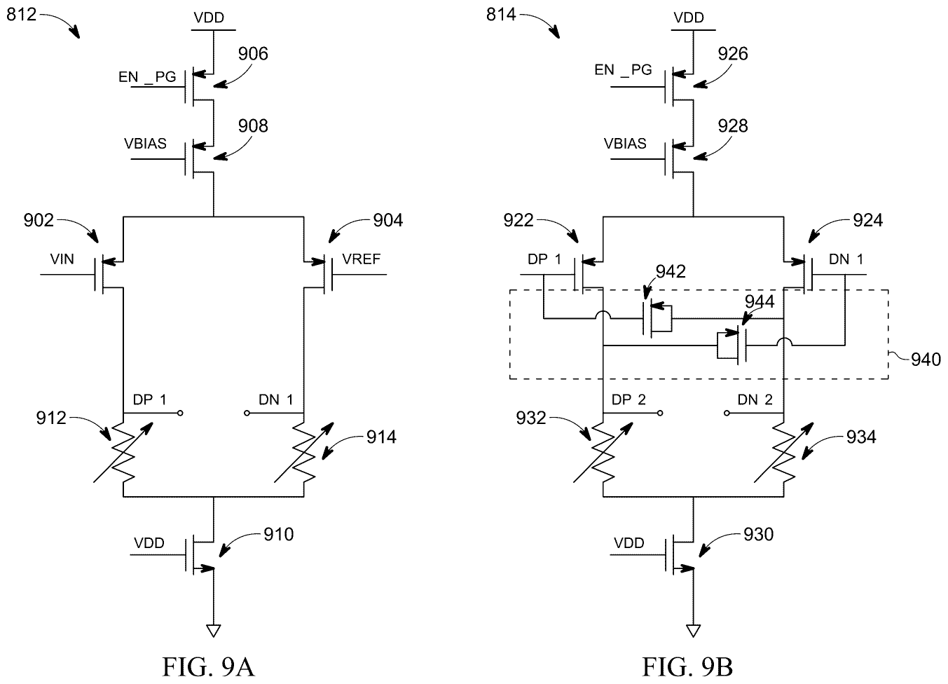

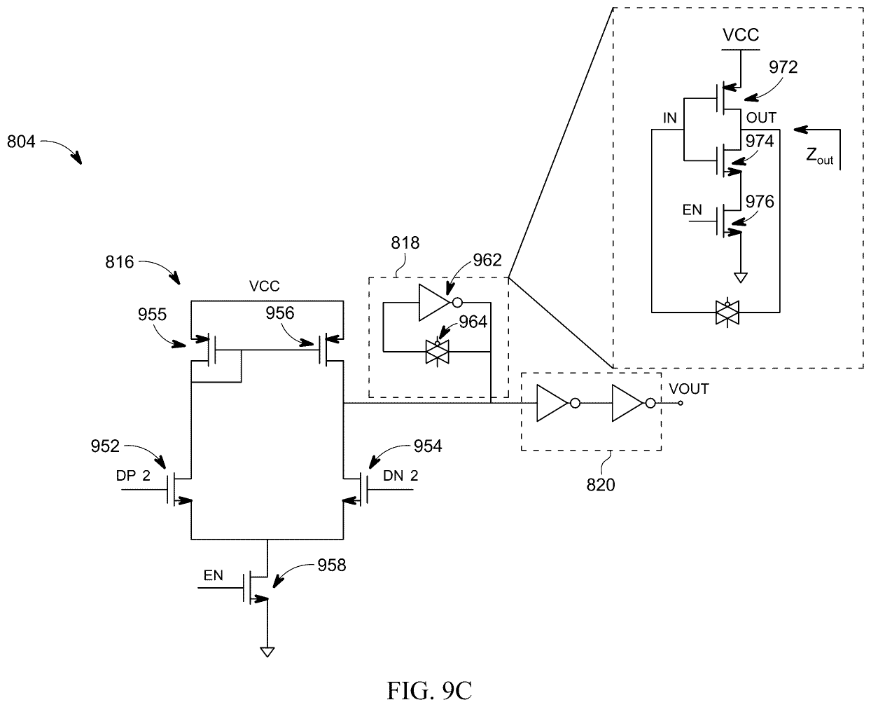

FIG. 9A illustrates a schematic circuit diagram of the first CML circuit 812. The first CML circuit 812 can include a first transistor 902 (e.g., a PMOS transistor) coupled to the input voltage at its gate terminal, and a second transistor 904 (e.g., a PMOS transistor) coupled to the reference voltage at its gate terminal. The first transistor 902 can output a first differential voltage (DP1). The second transistor 904 can output a second differential voltage (DN1). The first CML circuit 812 can further include a transistor 906 coupled to an enable signal at its gate terminal, a transistor 908 coupled to a bias voltage at its gate terminal, a transistor 910 coupled to a power supply voltage (V_{DD}), and a pair of load resistors 912, 914. In some implementations, the pair of load resistors 912, 914 can be variable resistors. The enable signal can activate the first CML circuit 812. The bias voltage can be used to generate a current source for the first CML circuit 812.

Referring back to FIG. 8, the second CML circuit 814 is coupled to the first CML circuit 812. The second CML circuit 814 can receive the differential voltages (DP1 and DN1) from the first CML circuit 812, and generate differential voltages (DP2 and DN2) that further amplify DP1 and DN1. The second CML circuit 814 can include a negative capacitor configured to offset parasitic capacitance (e.g., parasitic capacitance as a result of the pair of load resistor 912, 914 of the first CML circuit 812, and/or parasitic capacitance at input gates of the second CML circuit 814), thereby expanding the bandwidth and increasing the speed of the first CML circuit 812. The differential voltages (DP2, DN2) are output to the OTA circuit 816.

FIG. 9B illustrates a schematic circuit diagram of the second CML circuit 814, according to some aspects of the present disclosure. The second CML circuit 814 can include a third transistor 922 (e.g., a PMOS transistor) coupled to DP1 at its gate terminal, and a fourth transistor 924 (e.g., a PMOS transistor) coupled to DN1 at its gate terminal. The third transistor 922 can output the third differential voltage (DP2). The fourth transistor 924 can output the fourth differential voltage (DN2). The second CML circuit 814 can further include a transistor 926 coupled to an enable signal at its gate terminal, a transistor 928 coupled to a bias voltage at its gate terminal, a transistor 930 coupled to the power supply voltage (V_{DD}), and a pair of load resistors 932, 934.

In some implementations, the negative capacitor 940 can be formed based on two transistors (e.g., the fifth transistor 942 and the sixth transistor 944) through Miller effect. Each transistor is coupled between an input and an output of the second CML circuit 814 that have the same phase. The first differential voltage (DP1) and the fourth differential voltage (DN2) have the same phase. The second differential voltage (DN1) and the third differential voltage (DP2) have the same phase. As shown in FIG. 9B, the fifth transistor 942 is coupled between an input of the third transistor 922 (e.g., DP1) and an output of the fourth transistor 924 (e.g., DN2). The sixth transistor 944 is coupled between an input of the fourth transistor 924 (e.g., DN1) and an output of the third transistor 922 (e.g., DP2). In some implementations, the fifth transistor 942 can be a PMOS transistor with its gate coupled to DP1 and a terminal (e.g., drain or source) coupled to DN2, and the sixth transistor 944 can be a PMOS transistor with its gate coupled to DN1 and a terminal (e.g., drain or source) coupled to DP2. According to Miller effect, the equivalent capacitance (Cᵢₙ) at each input terminal of the second CML circuit can be Cᵢₙ=(1−|Aᵥ|)Cₚₘₒₛ, where Cₚₘₒₛ is the capacitance of the fifth capacitor 942 or the sixth capacitor 944, Aᵥ is the amplification gain of the second CML circuit 814. Since the absolute value of Aᵥ is greater than 1, Cᵢₙ is negative, so that it can offset the parasitic capacitance, which is positive.

In some implementations, the negative capacitor 940 can be formed based on other components such as capacitors, operational amplifiers, negative feedback circuit, etc. In some implementations, the negative capacitor 940 (e.g., formed based on two transistors) can be adjusted according to the parasitic capacitance in the first and the second CML circuit, which may be different for different processes, voltages or temperatures.

Referring back to FIG. 8, the second circuit 804 can receive the differential voltages (e.g., DP2, DN2) from the first circuit 802, and generate an amplified voltage of the input voltage based on the differential voltages. The OTA circuit 816 of the second circuit 804 can convert the differential voltages (DP2, DN2) from the second CML circuit 814 into a single-ended voltage, which is then received by the active inductor 818 and the inverters 820. The output voltage (Vₒᵤₜ) can be an amplified voltage of the input voltage (Vᵢₙ). In some implementations, the output voltage (Vₒᵤₜ) of the second circuit 804 can be sent to a deserializer (e.g., the deserializer 718 of FIG. 7) of the I/O interface. The deserializer which can convert serial data into parallel data, so that data can be written into the memory array in a faster and more efficient way. In some implementations, the output voltage (Vₒᵤₜ) of the second circuit 804 can be sent to a sense amplifier (e.g., the page buffer/sense amplifier 304 of FIG. 3, or the sense amplifier 510 of FIG. 5) of the memory device.

FIG. 9C illustrates a schematic circuit diagram of the second circuit 804, according to some aspects of the present disclosure. The OTA circuit 816 can include a seventh transistor 952 (e.g., a NMOS transistor) coupled to the third differential voltage (DP2) at its gate terminal, and an eight transistor 954 (e.g., a NMOS transistor) coupled to the fourth differential voltage (DN2) at its gate transistor. The OTA circuit 816 can further include a pair of transistors 955, 956 each having a terminal coupled to a power source voltage (Vcc), and a transistor 958 coupled to an enable signal at its gate terminal.

The active inductor 818 is coupled to an output of the OTA circuit 816. In some implementations, the active inductor 818 can be formed based on a first inverter 962 and a CMOS transmission gate 964 coupled in parallel. For example, the first inverter 962 can include a pair of PMOS transistor 972 and NMOS transistor 974, and a transistor 976 coupled to an enable signal at its gate terminal. The gate terminals of both the PMOS transistor 972 and the NMOS transistor 974 are coupled to an input of the first inverter 962, and another terminal of both the PMOS transistor 972 and the NMOS transistor 974 are coupled to an output of the first inverter 962. The CMOS transistor 964 is coupled between the input and the output of the first inverter 962. As such, the output impedance (Zₒᵤₜ) of the active inductor 818 is

$${Z}_{out} = \frac{{R}_{F} {C}_{i n} S + 1}{- {C}_{i n} S + {g}_{m}} ,$$

where Cᵢₙ is the input capacitance of the active inductor 818, gₘ is the transconductance of the first inverter 962, S is the complex frequency of the signal, and R_{F} is the equivalent impedance of the CMOS transmission gate 964.

In some implementations, the active inductor 818 can be formed based on other components such as inductors, transistors, resistors, operational amplifiers, etc.

The inverters 820 can include one or more second inverters coupled in series. The inverters 820 are coupled to the active inductor 818. The inverters 820 can output the amplified voltage (Vₒᵤₜ), and can perform pulse width shaping to adjust the duration of pulses when outputting Vₒᵤₜ.

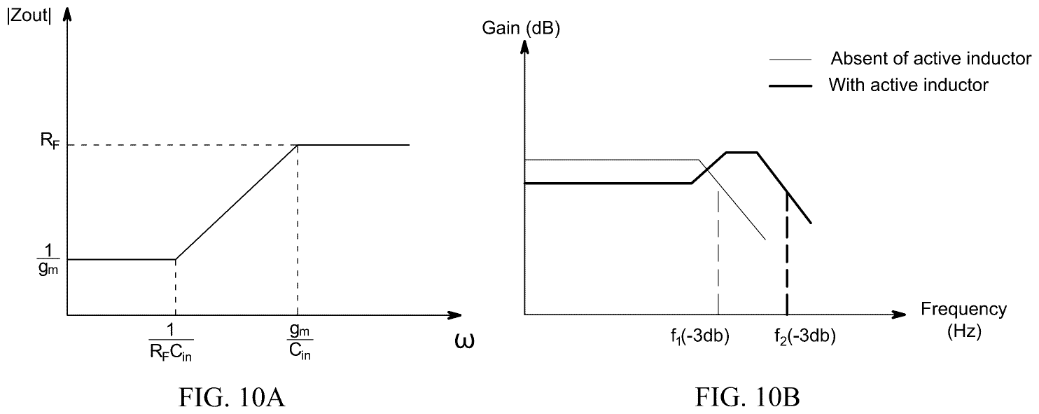

FIG. 10A illustrates an example frequency response curve of the active inductor 818, according to some aspects of the present disclosure. When the signal frequency increases from 0 to

$$\frac{1}{{R}_{F} {C}_{i n}} ,$$

the absolute value of the output impedance (|Zₒᵤₜ|) remains unchanged at

$$\frac{1}{{g}_{m}} .$$

When the signal frequency increases from

$$\frac{1}{{R}_{F} {C}_{i n}} to \frac{{g}_{m}}{{c}_{i n}} ,$$

|Zₒᵤₜ| increases from

$$\frac{1}{{g}_{m}}$$

to R_{F}. When the frequency further increases from

$$\frac{{g}_{m}}{{c}_{i n}} ,$$

|Zₒᵤₜ| remains unchanged at R_{F}. As such,

$$\frac{1}{{R}_{F} {C}_{i n}}$$

can be the zero point of the frequency response curve, which can expand the bandwidth and increase the speed of the OTA circuit 816. As shown in FIG. 10B, without the active inductor 818, the bandwidth of the OTA circuit 818 is f₁, where the amplification gain of the OTA circuit drops below −3 dB. By including the active inductor 818, the bandwidth of the OTA circuit 816 can be expanded to f₂, where the amplification gain of the OTA circuit does not drop under −3 dB until the frequency rises above f₂.

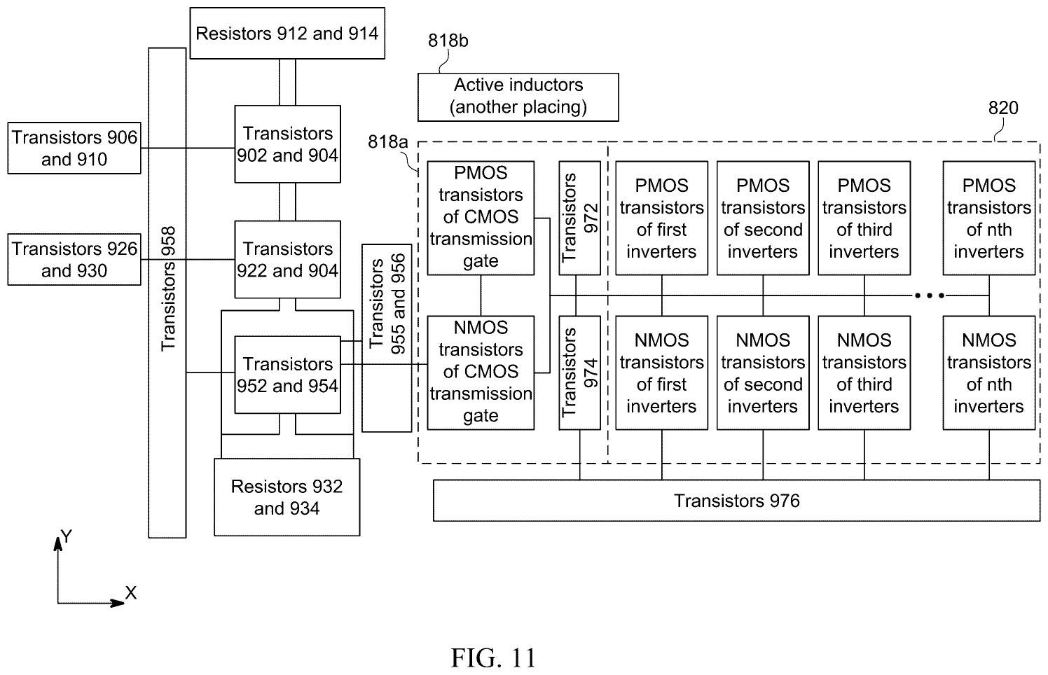

FIG. 11 illustrates an example floor plan 1100 of an I/O interface including a plurality of input buffers, according to some aspects of the present disclosure. Each of the plurality of input buffers can include a first CML circuit 812, a second CML circuit 814, an OTA circuit 816, an active inductor 818 and inverters 820, which can be arranged on a printed circuit board. Components of the circuits of the input buffers can be connected with each other through metal wiring, e.g., according to the schematic diagrams of FIGS. 9A-9C. It should be noted that the example floorplan 1110 only shows a portion of components of the I/O interface, and other components not shown in FIG. 11 may be included in the input buffers as well.

In some implementations, transistors 906 and 910 of the first CML circuits 812 and transistors 926 and 930 of the second CML circuits 814 can be placed on a first side of the transistors 958 of the OTA circuits 816. Resistors 912 and 914 of the first CML circuits 812, transistors 902 and 904 of the first CML circuits 812, transistors 922 and 924 of the second CML circuits 814, transistors 952 and 954 of the OTA circuits 816, and resistors 932 and 934 of the second CML circuits 814 are placed on a second side of the transistors 958. Transistors 906 and 910 are connected to transistors 902 and 904, transistors 926 and 930 are connected to transistors 922 and 924, transistors 955, 956 and 958 are connected to transistors 952 and 954, respectively, through metal wiring (e.g., in one or more connection layers of the second semiconductor structure 604).

The active inductors 818 can be placed at different positions on the floor plan 1100. In some implementations, at least a portion of the active inductor 818 is placed between the OTA circuit 816 and the inverters 820.

In some implementations, as shown by a first position 818a, at least a portion of the transistors included in the active inductors 818 (e.g., PMOS transistors and NMOS transistors of the CMOS transmission gate 964, and PMOS transistors 972 and NMOS transistors 974 of the first inverter 962) are placed between the transistors 955, 956 of the OTA circuit and the transistors of the inverters 820 in X direction. In such case, channels (e.g., made of polysilicon) of the transistors of the CMOS transmission gate 964 can be arranged in a different direction (e.g., perpendicular to) compared to channels of the transistors of the inverters 820. For example, the channel of each transistor of the CMOS transmission gate 964 is set along a first direction (e.g., Y direction), while channels of the other transistors (e.g., transistors 955, 956, transistors of the inverters 820) in the input buffer are set along a second direction (X direction) that is perpendicular to the first direction. As such, less metal wiring is needed to connect the active inductors 818 to the OTA circuit 816 and to the inverters 920, so that the parasitic capacitance resulting from the metal wiring can be reduced, and the performance of the input buffer can be improved.

In some implementations, as shown by a second position 818b, at least a portion of the transistors included in the active inductors 818 (e.g., PMOS transistors and NMOS transistors of the CMOS transmission gate 964, and PMOS transistors 972 and NMOS transistors 974 of the first inverter 962) are placed above the transistors 955 and 956 of the OTA circuit and the transistors of the inverters 820. For example, the transistors 972 and 974 of the first inverter 962 are placed between the transistors 955 and 956 and the transistors of the inverters 820 along a third direction (e.g., X direction), while transistors of the CMOS transmission gate 964 are placed in the second position 818b, which is offset from the third direction. In such case, channels of the transistors of the CMOS transmission gate 964 can be arranged in a parallel direction compared to channels of the transistors of the inverters 820. For example, channels of all transistors in the input buffers are set along X direction. In some cases, placing the active inductors 818 in the second position 818b may require more metal wiring for connection than placing the active inductors 818 in the first position 818a.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as glass, plastic, or sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate. The terms “operation” and “step” can be used interchangeably to describe a process.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. An input buffer of a memory device, comprising:
a first circuit configured to:
receive an input voltage and a reference voltage; and
generate differential voltages based on the input voltage and the reference voltage; and
a second circuit coupled to the first circuit, wherein the second circuit is configured to:
receive the differential voltages from the first circuit; and
generate an amplified voltage of the input voltage based on the differential voltages, wherein the second circuit comprises an active inductor.

2. The input buffer of claim 1, wherein the active inductor comprises a CMOS transmission gate and a first inverter coupled in parallel.

3. The input buffer of claim 1, wherein the first circuit comprises:
a first current-mode logic (CML) circuit comprising:
a first transistor that receives the input voltage and outputs a first differential voltage; and
a second transistor that receives the reference voltage and outputs a second differential voltage; and
a second CML circuit comprising:
a third transistor that receives the first differential voltage and outputs a third differential voltage; and
a fourth transistor that receives the second differential voltage and outputs a fourth differential voltage.

4. The input buffer of claim 3, wherein the second CML circuit comprises a negative capacitor.

5. The input buffer of claim 4, wherein the negative capacitor comprises:
a fifth transistor coupled between an input of the third transistor and an output of the fourth transistor; and
a sixth transistor coupled between an input of the fourth transistor and an output of the third transistor.

6. The input buffer of claim 3, wherein the second circuit comprises an operational transconductance-amplifier (OTA) circuit comprising:
a seventh transistor that receives the third differential voltage; and
an eighth transistor that receives the fourth differential voltage, wherein the active inductor is coupled to an output of the OTA circuit.

7. The input buffer of claim 6, wherein the active inductor is coupled to one or more second inverters that are coupled in series, wherein the one or more second inverters output the amplified voltage.

8. The input buffer of claim 7, wherein the first circuit and the second circuit are placed on a printed circuit board (PCB), and wherein at least a portion of the active inductor is placed between the OTA circuit and the one or more second inverters.

9. The input buffer of claim 8, wherein a CMOS transmission gate and a first inverter of the active inductor are placed, on the PCB, between:
transistors comprised in the OTA circuit; and
transistors comprised in the one or more second inverters.

10. The input buffer of claim 9, wherein a channel of a transistor comprised in the CMOS transmission gate is arranged along a first direction, wherein channels of the transistors comprised in the one or more second inverters are arranged in a second direction, and
wherein the first direction is perpendicular to the second direction.

11. The input buffer of claim 8, wherein a first inverter of the active inductor is placed between transistors comprised in the OTA circuit and transistors comprised in the one or more second inverters along a third direction, and
wherein a CMOS transmission gate of the active inductor is offset from the third direction.

12. The input buffer of claim 11, wherein a channel of a transistor comprised in a CMOS transmission gate of the active inductor is arranged along a first direction, wherein channels of the transistors comprised in the one or more second inverters are arranged in a second direction, and
wherein the first direction is parallel to the second direction.

13. A memory device, comprising an input/output interface that comprises an input buffer, wherein the input buffer comprises:
a first circuit configured to:
receive an input voltage and a reference voltage; and
generate differential voltages based on the input voltage and the reference voltage; and
a second circuit coupled to the first circuit, wherein the second circuit is configured to:
receive the differential voltages from the first circuit; and
generate an amplified voltage of the input voltage based on the differential voltages, wherein the second circuit comprises an active inductor.

14. The memory device of claim 13, wherein the active inductor comprises a CMOS transmission gate and a first inverter coupled in parallel.

15. The memory device of claim 13, wherein the first circuit comprises:
a first current-mode logic (CML) circuit comprising:
a first transistor that receives the input voltage and outputs a first differential voltage; and
a second transistor that receives the reference voltage and outputs a second differential voltage; and
a second CML circuit comprising:
a third transistor that receives the first differential voltage and outputs a third differential voltage; and
a fourth transistor that receives the second differential voltage and outputs a fourth differential voltage.

16. The memory device of claim 15, wherein the second CML circuit comprises a negative capacitor.

17. The memory device of claim 16, wherein the negative capacitor comprises:
a fifth transistor coupled between an input of the third transistor and an output of the fourth transistor; and
a sixth transistor coupled between an input of the fourth transistor and an output of the third transistor.

18. The memory device of claim 15, wherein the second circuit comprises an operational transconductance-amplifier (OTA) circuit comprising:
a seventh transistor that receives the third differential voltage; and
an eighth transistor that receives the fourth differential voltage, wherein the active inductor is coupled to an output of the OTA circuit.

19. The memory device of claim 18, wherein the active inductor is coupled to one or more second inverters that are coupled in series, wherein the one or more second inverters output the amplified voltage.

20. A memory system, comprising:
a memory device comprising an input/output interface that comprises an input buffer, wherein the input buffer comprises:
a first circuit configured to:
receive an input voltage and a reference voltage; and
generate differential voltages based on the input voltage and the reference voltage; and
a second circuit coupled to the first circuit, wherein the second circuit is configured to:
receive the differential voltages from the first circuit; and
generate an amplified voltage of the input voltage based on the differential voltages, wherein the second circuit comprises an active inductor; and
a memory controller coupled to the memory device and configured to control the memory device.
